(19) United States
(12) Patent Application Publication
(10) Pub. No.: US 2025/0185153 A1
(43) Pub. Date: Jun. 5, 2025

(54) BGA Radio Frequency Module, Substrate for BGA Radio Frequency Module and Optical Communication Module

(71) Applicant: Nippon Telegraph and Telephone Corporation, Tokyo (JP)

(72) Inventors: Masayuki Takahashi, Musashino-shi, Tokyo (JP); Ken Tsuzuki, Musashino-shi, Tokyo (JP)

(21) Appl. No.: 18/844,362

(22) PCT Filed: Mar. 9, 2022
(86) PCT No.: PCT/JP2022/010287

§ 371 Date: Sep. 5, 2024

(51) Int. Cl. H05K 1/02; H05K 1/11

(52) U.S. Cl. CPC H05K 1/024; H05K 1/112; H05K 1/115; H05K 2201/10734

(57) ABSTRACT

Provided are a BGA radio frequency module, a substrate for a BGA radio frequency module, and an optical communication module, wherein realize downsizing of an optical communication module without lowering impedance between a pad and a solder ball. The BGA radio frequency module according to the present disclosure includes a differential signal pair including a first signal pad and a second signal pad, a first ground pad disposed adjacent to the first signal pad, a second ground pad disposed adjacent to the second signal pad, at least one third ground pad disposed at a position spaced from the first signal pad more than a distance between the first signal pad and the first ground pad, and at least one fourth ground pad disposed at a position spaced from the second signal pad more than a distance between the second signal pad and the second ground pad.

### TECHNICAL FIELD

The present disclosure relates to a BGA radio frequency module, a substrate for a BGA radio frequency module, and an optical communication module including the BGA radio frequency module and the substrate.

### BACKGROUND ART

In recent years, small-sized optical transceivers capable of increasing the transmission speed per module footprint have been put into practical use in the optical communication industry. As an example, it has already been reported that a small-sized optical transceiver of approximately 18.35 mm×58.26 mm×8.5 mm can be realized in a form factor of a transceiver for optical communication called Quad Small Form-factor Pluggable Double Density (hereinafter referred to as QSFP-DD). In such a small-sized optical transceiver, application of a radio frequency module including a ball grid array (hereinafter referred to as BGA), which has been conventionally used for an IC or the like, to an optical communication module to be mounted has been advanced. In addition, a technique of installing such a BGA radio frequency module on a printed circuit board (hereinafter referred to as PCB) is also in progress (e.g., refer to Non Patent Literature 1). In recent years, there is an increasing demand for further downsizing of an optical transceiver, and therefore, there is an increasing demand for further downsizing of an optical communication module in which a BGA radio frequency module is installed on a PCB.

FIG. 1 is a diagram illustrating an example of a structure of a BGA radio frequency module 10 according to a conventional technique, FIG. 1(a) illustrates a plan view as viewed from a back surface (a surface facing a PCB 20 in FIG. 3 to be described later), and FIG. 1(b) illustrates a cross-sectional view at a position of the section line Ib-Ib. As shown in FIG. 1, the BGA radio frequency module 10 according to the conventional technique includes a module member 11, and a plurality of pads 12 arranged at equal intervals in a longitudinal direction (X direction in FIG. 1) and a width direction (Y direction in FIG. 1) on a back surface of the module member 11. Here, an embodiment of seven rows and four columns in which seven pads 12 are arranged in the X direction and four pads 12 are arranged in the Y direction is shown as an example. Moreover, polymers, ceramics, or the like may be applied to the module member 11, and aluminum, copper, or the like may be applied to the pads 12.

FIG. 2 is a diagram illustrating an example of a structure of the PCB 20 for mounting the BGA radio frequency module 10 according to the conventional technique, FIG. 2(a) illustrates a plan view as viewed from the upper surface side (a surface opposed to the BGA radio frequency module 10 in FIG. 3 to be described later), and FIG. 2(b) illustrates a cross-sectional view at a position of the section line IIb-IIb. As shown in FIG. 2, the PCB 20 includes a stacked substrate 21 in which a plurality of dielectric portions 211a to 211c and a plurality of ground planes 212a to 212c are stacked, a plurality of pads 22 arranged at equal intervals in a longitudinal direction (X direction in FIG. 2) and a width direction (Y direction in FIG. 2) on an upper surface of the stacked substrate 21, and through-hole vias 23a to 23c that electrically connect a part of the plurality of pads 22 and the ground planes 212a to 212c. Here, as in FIG. 1, an embodiment of seven rows and four columns in which seven pads 22 are arranged in the X direction and four pads 22 are arranged in the Y direction is shown as an example. Some pads 22 connected with the ground planes 212a to 212c function as ground pads that stabilize signals. In FIG. 2, these ground pads are connected with the ground plane 212c via the through-hole vias 23a to 23c. As shown in FIG. 2(a), other pads such as signal terminals are connected with an external circuit via surface layer wiring 24 formed on the upper surface of the PCB 20. Alternatively, other pads are wired to be connected with inner layer wiring formed on the substrate in a lower layer via the through-hole vias.

By installing the above-described BGA radio frequency module 10 on the PCB 20 in such a manner, an optical communication module 30 mounted on a small-sized optical transceiver is manufactured.

FIG. 3 is a diagram illustrating an example of a structure of the optical communication module 30 in which the BGA radio frequency module 10 is mounted on the PCB 20, FIG. 3(a) is a plan view of the BGA radio frequency module 10 as viewed from above, and FIG. 3(b) is a cross-sectional view at a position of the section line IIIb-IIIb. As shown in FIG. 3, in the optical communication module 30, the BGA radio frequency module 10 is installed on the PCB 20, and both are electrically connected via solder balls 31 disposed between the pads 12 and the pads 22. Typically, the optical communication module 30 may be manufactured by forming the solder balls 31 on the pads 12 of the BGA radio frequency module 10 and reflowing them while arranged on the PCB 20.

When the optical communication module 30 is applied to a transceiver for optical communication, the pads 12 of the BGA radio frequency module serves as various terminals. In addition to the above-described ground pads, the terminal may further include a DC terminal for supplying power, an analog or digital control terminal, and a signal terminal for inputting and outputting an electric signal. Although the number of DC terminals varies greatly depending on the module, a total of eight pairs of differential signal pairs including four pairs of transmission and four pairs of reception are often used as the signal terminals in the case of an optical communication module for coherent optical communication. Moreover, signal terminals of the optical communication module are usually collected at one end of the module in order to input and output signals to and from a signal processing processor adjacent to the optical communication module, or a host device constituting the optical communication system.

In order to downsize such an optical communication module, there is a method of narrowing the interval between pads 12, between pads 22, and between solder balls 31, and densely arranging the terminals (densifying the terminals). However, densifying the terminals causes an increase in capacitance between solder balls 31, and accordingly, there is a problem that capacitance between terminals such as ground pads or signal terminals increases. If the capacitance between adjacent signal terminals (differential signal pair) or between the signal terminal and the ground pad terminal increases, the impedance lowers, the impedance matching cannot be obtained, and, as a result, the radio frequency pass characteristics (lowering of cutoff frequency) or the radio frequency reflection characteristics deteriorate. As described above, when the optical communication module in which the BGA radio frequency module is installed on the PCB is downsized, signal quality may lower if terminals are densified.

To solve such a problem, it is known to downsize the pads 12 and 22 and the solder balls 31 as a conventional technique for suppressing an increase in capacitance between terminals. However, since the pads 12 and 22 need to be connected with the ground plane 212c via the through-hole vias 23a to 23c and the lead wires as described above, it is difficult to make the pads 12 and 22 and the solder balls 31 smaller than a certain size. Moreover, due to the downsizing of the pads 12 and 22 and the solder balls 31, another problem that installation becomes difficult may also occur.

As an example, sizes of the pads 12 and 22 and the solder balls 31 in a case of realizing the optical communication module 30 with the above-described small-sized form factor QSFP-DD having a size of approximately 18.35 mm×58.26 mm×8.5 mm are considered. When the PCB 20 is mounted on an exterior having a width (length in Y direction in FIGS. 1 and 2) of 18.35 mm, the width of the substrate of the PCB 20 is required to be smaller than that of the exterior, and is thus approximately 14 to 16 mm.

On the other hand, when focusing on the arrangement of the terminals, when the differential signal pairs are arranged in ground-signal-signal-ground (GSSG), two pairs of differential signal pairs are seven terminals of GSSGSSG if the adjacent ground pads are shared, and the differential signals can be arranged in a smaller region. In a case of assuming such an arrangement, if the optical communication module 30 is for coherent optical communication, the number of differential signal pairs is eight, and therefore, the total number of terminals is 25. The interval between solder balls 31 is generally approximately 0.25 to 0.8 mm, but is set to 0.5 mm here as an example. In this case, when the signal terminals are collected at one end, a width of approximately 12 mm is required, and the width falls within a range of 14 to 16 mm corresponding to the width of the PCB 20 described above. However, the standard of the BGA is defined in Japan Electronics and Information Technology Industries Association (JEITA) or the like. When the interval between solder balls 31 is 0.5 mm, the diameter of the pad is set to approximately φ0.3 mm as a nominal value. Therefore, it can be said that there is a substantial limit to the downsizing of the pad.

Moreover, the sizes of the pads and the solder balls are also limited from the package side of the optical communication module mounted on the BGA. For example, as in Non Patent Literature 1, a restraint for a ceramic coat having a width of 70 μm is required in order to secure the strength of the pad when a ceramic package material is used. Therefore, the diameter of the pad is substantially φ0.44 mm, and the gap between the pad and the adjacent pad is as narrow as approximately 60 μm. Accordingly, the capacitance increases, the impedance lowers, and therefore the radio frequency pass characteristics (lowering of cutoff frequency) and the radio frequency reflection characteristics may be deteriorated.

From the above, in an optical communication module (e.g., the optical communication module 30) in which a BGA radio frequency module is installed on a PCB and effective for downsizing an optical transceiver, although further downsizing by densifying the terminals is desired, lowering of signal quality due to lowering of impedance due to the densification of terminals is a problem. In view of such a problem, it can be said that there is a limit from the viewpoint of restriction by standards or the like in a conventional technique of reducing the size of terminals (pads and solder balls), and another method is required.

### CITATION LIST

### Non Patent Literature

Non Patent Literature 1: S. Yamanaka, et al., “Silicon Photonics Coherent Optical Subassembly with EO and OE Bandwidths of Over 50 GHz” OFC 2020. (2020)

### SUMMARY OF INVENTION

The present disclosure has been made in view of the above problems, and an object thereof is to provide a BGA radio frequency module, a substrate for a BGA radio frequency module, and an optical communication module including at least one of the BGA radio frequency module or the substrate, which realize downsizing of the optical communication module without lowering impedance between a pad and a solder ball.

To solve the above problem, the present disclosure provides a BGA radio frequency module including: a module member; a differential signal pair that is disposed on a back surface of the module member and includes a first signal pad and a second signal pad adjacent to the first signal pad; a first ground pad disposed adjacent to the first signal pad; a second ground pad disposed adjacent to the second signal pad; at least one third ground pad disposed at a position spaced from the first signal pad more than a first distance between the first signal pad and the first ground pad and a second distance between the second signal pad and the second ground pad; and at least one fourth ground pad disposed at a position spaced from the second signal pad more than the first distance and the second distance.

### BRIEF DESCRIPTION OF DRAWINGS

FIG. 1 is a diagram illustrating an example of a structure of the BGA radio frequency module 10 according to a conventional technique, FIG. 1(a) illustrates a plan view as viewed from a back surface, and FIG. 1(b) illustrates a cross-sectional view at a position of the section line Ib-Ib.

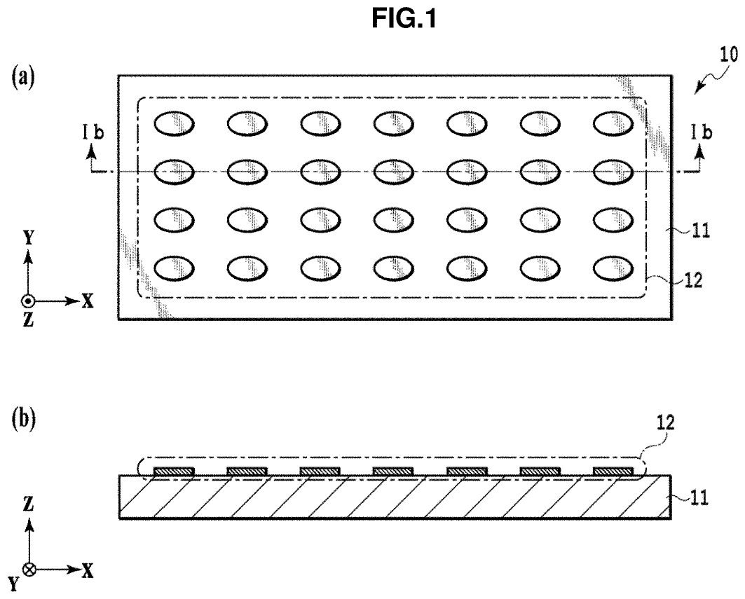

FIG. 2 is a diagram illustrating an example of a structure of the PCB 20 for mounting the BGA radio frequency module 10 according to the conventional technique, FIG. 2(a) illustrates a plan view as viewed from an upper surface side, and FIG. 2(b) illustrates a cross-sectional view at a position of the section line IIb-IIb.

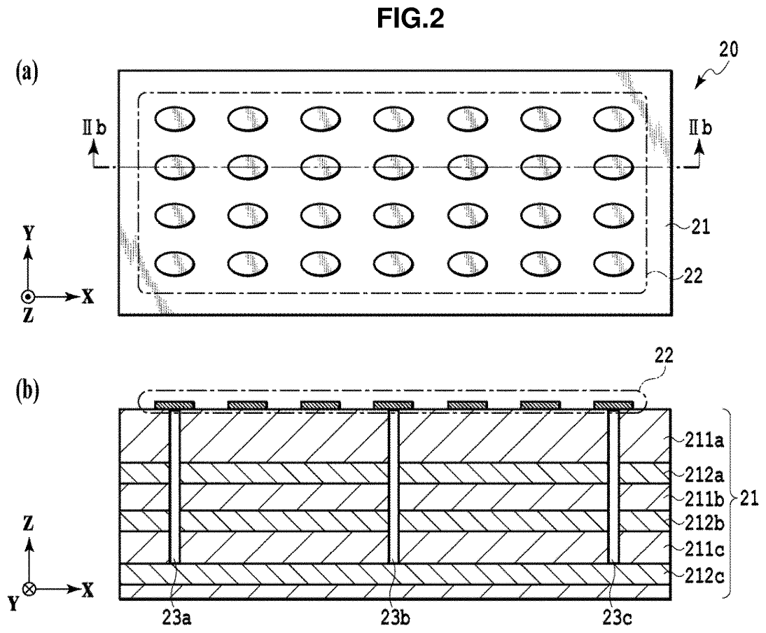

FIG. 3 is a diagram illustrating an example of a structure of the optical communication module 30 in which the BGA radio frequency module 10 is mounted on the PCB 20, FIG. 3(a) is a plan view of the BGA radio frequency module 10 as viewed from above, and FIG. 3(b) is a cross-sectional view at a position of the section line IIIb-IIIb.

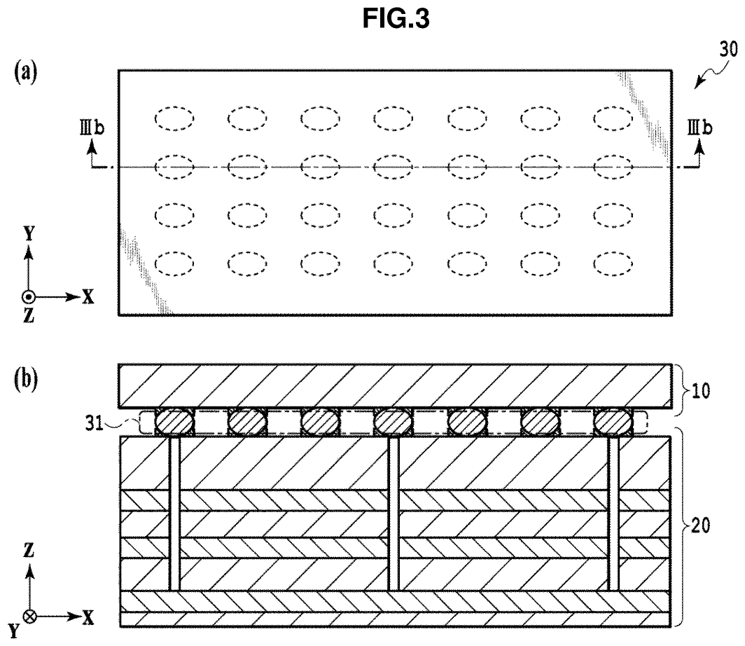

FIG. 4 is a diagram illustrating a structure of a BGA radio frequency module 40 used in an optical communication module according to a first embodiment of the present disclosure, FIG. 4(a) is a plan view of the BGA radio frequency module 40 as viewed from a back surface side, FIG. 4(b) is a cross-sectional view at a position of the section line IVb-IVb, and FIG. 4(c) is a plan view of a variation.

FIG. 5 is a diagram illustrating a structure of an optical communication module 50 in which the BGA radio frequency module 40 according to the first embodiment of the present disclosure is mounted on a PCB 51, FIG. 5(a) is a plan view of the PCB 51 as viewed from above, and FIG. 5(b) is a cross-sectional view at a position of the section line Vb-Vb.

FIG. 6 is a diagram illustrating a structure of a BGA radio frequency module 60 according to a second embodiment of the present disclosure, FIG. 6(a) is a plan view of the BGA radio frequency module 60 as viewed from a back surface side, and FIG. 6(b) is a cross-sectional view at a position of the section line VIb-VIb.

FIG. 7 is a diagram illustrating a structure of a BGA radio frequency module 70 according to a second embodiment of the present disclosure, FIG. 7(a) is a plan view of the BGA radio frequency module 70 as viewed from a back surface side, and FIG. 7(b) is a cross-sectional view at a position of the section line VIIb-VIIb.

FIG. 8 is a diagram illustrating a structure of a PCB 80 according to a fourth embodiment of the present disclosure, FIG. 8(a) is a plan view of the PCB 80 as viewed from an upper surface side, and FIG. 8(b) is a cross-sectional view at a position of the section line VIIIb-VIIIb.

### DESCRIPTION OF EMBODIMENTS

Hereinafter, various embodiments of the present disclosure is described in detail with reference to the drawings. The same or similar reference signs denote the same or similar components, and redundant description may be omitted. The materials and numerical values are for illustrative purposes and are not intended to limit the scope of the disclosure. The following description is an example, and some configurations may be omitted, modified, or implemented together with additional configurations without departing from the gist of an embodiment of the present disclosure.

Unlike conventional techniques, BGA radio frequency modules in the present disclosure have a structure in which a distance between a signal pad and an adjacent ground pad is shorter than a distance between the signal pad and each of the other ground pads. The PCB also has a structure in which at least a part of the ground plane is eliminated. With such a structure, since the distance between each of the signal pads and each of the ground pads and the distance between each of the signal pads and the ground plane are longer than those in conventional techniques, it is possible to suppress lowering of impedance.

### First Embodiment

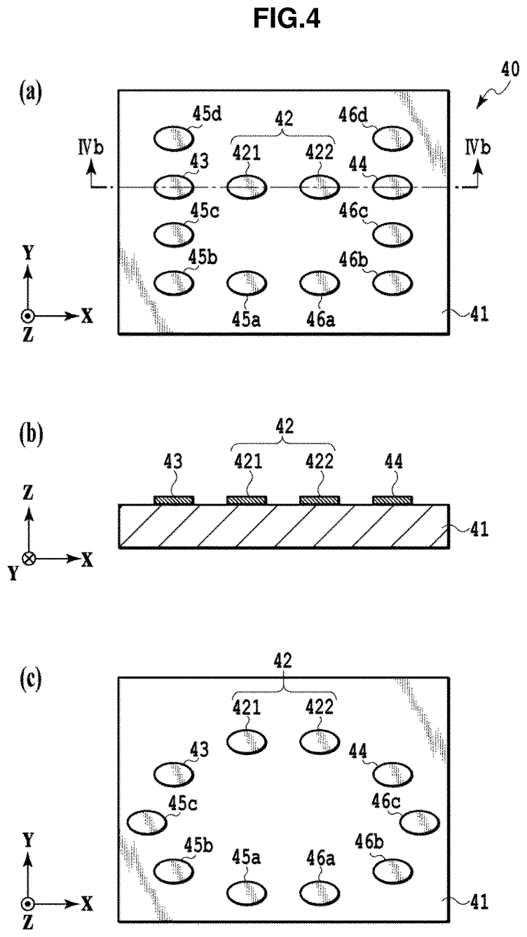

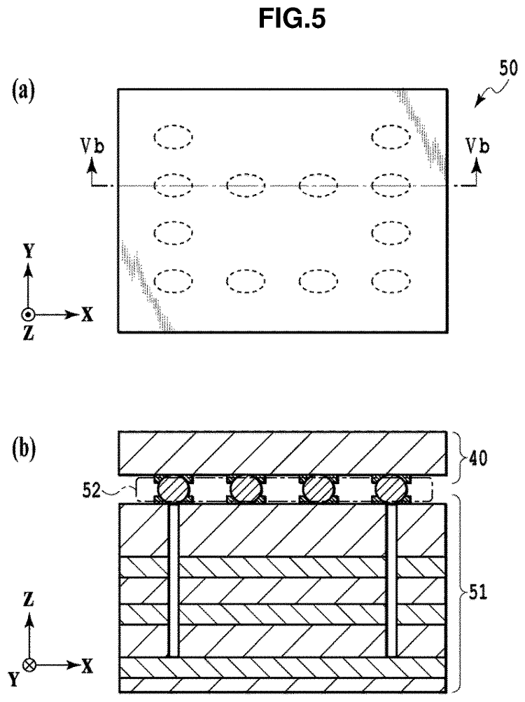

FIG. 4 is a diagram illustrating a structure of the BGA radio frequency module 40 used in an optical communication module according to the first embodiment of the present disclosure, FIG. 4(a) is a plan view of the BGA radio frequency module 40 as viewed from a back surface (a surface facing the PCB 51 in FIG. 5 to be described later) side, FIG. 4(b) is a cross-sectional view at a position of the section line IVb-IVb, and FIG. 4(c) is a plan view of a variation. As shown in FIG. 4, the BGA radio frequency module 40 according to the first embodiment of the present disclosure includes a differential signal pair 42 including a first signal pad 421 and a second signal pad 422 adjacent to the first signal pad 421 on a back surface of a module member 41, a first ground pad 43 disposed adjacent to the first signal pad 421, a second ground pad 44 disposed adjacent to the second signal pad 422, at least one third ground pad 45a to 45d each disposed at a position spaced from the first signal pad more than a distance between the first signal pad 421 and the first ground pad 43 and a second distance between the second signal pad and the second ground pad, and a fourth ground pad 46a to 46d each disposed at a position spaced more than the distance between the second signal pad 422 and the second ground pad 44.

Regarding the distance between a signal pad and a ground pad, when considering the first signal pad 421 as a reference, the distance between the first signal pad 421 and the first ground pad 43 is the shortest, and the distance between the first signal pad 421 and each of the ground pads (e.g., a third ground pad 45) is always longer than the distance between the first signal pad 421 and the first ground pad 43. Similarly, when considering the second signal pad 422 as a reference, the distance between the second signal pad 422 and the second ground pad 44 is the shortest, and the distance between the second signal pad 422 and each of the ground pads (e.g., a fourth ground pad 46) is always longer than the distance between the second signal pad 422 and the second ground pad 44. Although FIG. 4 illustrates an embodiment in which four third ground pads 45a to 45d and four fourth ground pads 46a to 46d are arranged, the number of the third ground pads and the fourth ground pads to be arranged is not limited as long as the distance relationship described above is obtained.

Moreover, although FIG. 4(a) illustrates an embodiment in which the signal pads and the ground pads are arranged in a quadrangular shape on the XY plane, the arrangement manner is not limited thereto, and, for example, the signal pads and the ground pads may be arranged in a substantially circumferential shape or a substantially hexagonal shape (honeycomb) as shown in FIG. 4(c).

Furthermore, each signal pad and each ground pad may further include a ceramic coat restraint (not shown) for strength reinforcement. Although it is preferable that the width of the ceramic coat is approximately 70 μm, the width is not limited thereto.

FIG. 5 is a diagram illustrating a structure of the optical communication module 50 in which the BGA radio frequency module 40 according to the first embodiment of the present disclosure is mounted on the PCB 51, FIG. 5(a) is a plan view of the PCB 51 as viewed from above, and FIG. 5(b) is a cross-sectional view at a position of the section line Vb-Vb. As shown in FIG. 5, the optical communication module 50 according to the first embodiment of the present disclosure has a structure in which the above-described BGA radio frequency module 40 is installed on the PCB 51 via a plurality of solder balls 52. Here, the signal pads and the ground pads installed on the PCB 51 side are arranged to face each other so that the signal pads and the ground pads of the BGA radio frequency module 40 can be connected with each other via the solder balls 52. Moreover, as in the PCB 20 according to the conventional technique, the PCB 51 includes a stacked substrate in which dielectric portions and ground planes are stacked, through-hole vias that electrically connect the ground planes and the ground pads, and surface layer wiring that is electrically connected with the signal pads. Note that the signal pads may be connected with the inner layer wiring via the through-hole vias.

In the BGA radio frequency module 40 having such a form and the optical communication module 50 including the BGA radio frequency module 40, the distance between each of the third ground pads 45 and the first signal pad 421 and the distance between each of the fourth ground pads 46 and the second signal pad 422 are longer than the distance from the first ground pad 43 and the distance from the second ground pad 44 unlike a conventional technique in which pads are arranged at equal intervals. As a result, since the distance between each of the signal pads and each of the ground pads is longer than that in conventional cases, it is possible to suppress lowering of impedance and to suppress deterioration of signal quality.

### Second Embodiment

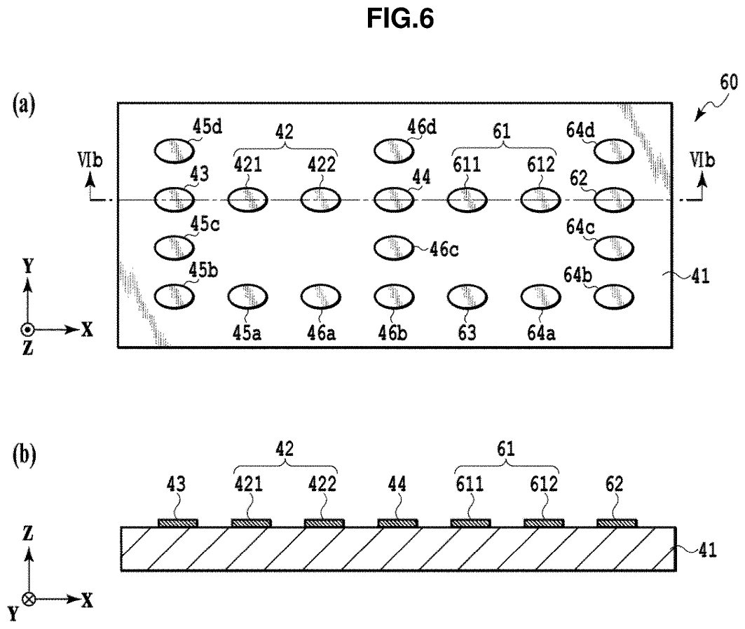

FIG. 6 is a diagram illustrating a structure of the BGA radio frequency module 60 according to the second embodiment of the present disclosure, FIG. 6(a) is a plan view of the BGA radio frequency module 60 as viewed from a back surface side, and FIG. 6(b) is a cross-sectional view at a position of the section line VIb-VIb. As shown in FIG. 6, the BGA radio frequency module 60 according to the second embodiment of the present disclosure has a structure in which a plurality of BGA radio frequency modules are coupled by sharing at least some of signal pads and ground pads in the above-described BGA radio frequency module 40. As an example, the BGA radio frequency module 60 further includes a differential signal pair 61 including a first signal pad 611 and a second signal pad 612, a fifth ground pad 62 adjacent to the second signal pad 612, a sixth ground pad 63 disposed at a position where the distance from the first signal pad 611 is longer than the distance between the first signal pad 611 and the second ground pad 44, and sixth ground pads 64a to 64d each disposed at a position where the distance from the second signal pad 612 is longer than the distance between the second signal pad 612 and the fifth ground pad 62 as shown in FIG. 6. Here, the second ground pad 44 and the fourth ground pads 46b and 64d are shared as ground pads of the first signal pad 611. However, a signal pad and a ground pad to be shared are not limited thereto, and any ground pad or any signal pad included in the BGA radio frequency module 60 may be shared as long as the arrangement of GSSGSS . . . described above is maintained.

Note that the BGA radio frequency module 60 may be further provided with an additional ground pad as long as the above-described distance relationship between the signal pads and the ground pads is obtained as in the first embodiment.

Moreover, although FIG. 6 illustrates a embodiment in which the signal pads and the ground pads are arranged in a quadrangular shape on the XY plane, the arrangement manner is not limited thereto, and for example, the signal pads and the ground pads may be arranged on a substantially circular circumference.

In addition, each pad may further include a ceramic coat restraint (not shown) for strength reinforcement. Although it is preferable that the width of the ceramic coat is approximately 70 μm, the width is not limited thereto.

As in the first embodiment, in an optical communication module produced by installing the BGA radio frequency module 60 on a PCB, the distance between each of the signal pads and each of the ground pads is longer than that in conventional optical communication modules, and therefore, it is possible to prevent lowering of impedance and suppress deterioration of signal quality.

### Third Embodiment

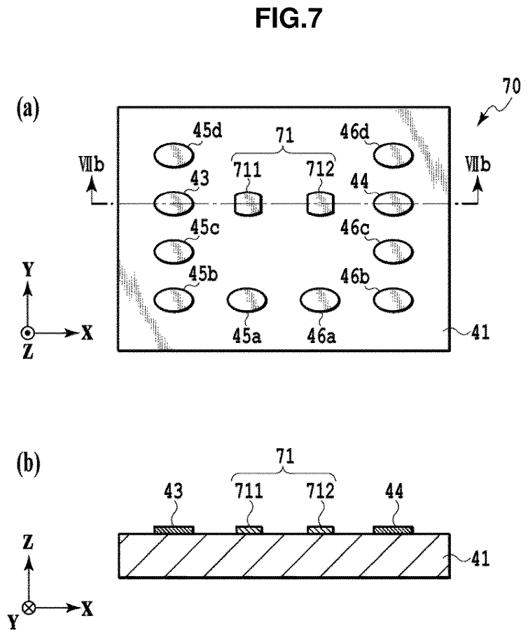

FIG. 7 is a diagram illustrating a structure of the BGA radio frequency module 70 according to the second embodiment of the present disclosure, FIG. 7(a) is a plan view of the BGA radio frequency module 70 as viewed from a back surface side, and FIG. 7(b) is a cross-sectional view at a position of the section line VIIb-VIIb. As shown in FIG. 7, the BGA radio frequency module 70 according to the third embodiment of the present disclosure is in an embodiment in which the first signal pad 421 in the BGA radio frequency module 40 is replaced by a first signal pad 711 and the second signal pad 422 is replaced by a second signal pad 712. The present embodiment is different from the first and second embodiments in that the first signal pad 711 and the second signal pad 712 each have a shape in which at least a part in the width direction is scraped off. However, the signal pads and the ground pads are arranged such that the distance between the first signal pad 711 and the first ground pad 43 and the distance between the second signal pad 712 and the second ground pad 44 are the shortest, as in the first and second embodiments.

Note that, although the BGA radio frequency module 70 is depicted to have a form not having the coupling described in the second embodiment in FIG. 7, the BGA radio frequency module 70 may be coupled by sharing at least some of the signal pads and at least some of the ground pads as in the second embodiment.

Moreover, as in the first embodiment, the arrangement in the BGA radio frequency module 60 is not limited to a quadrangular shape as long as the above-described distance is obtained. Moreover, each pad may further include a ceramic coat restraint (not shown) for strength reinforcement.

Even in an optical communication module in which such a BGA radio frequency module 70 is installed on a PCB, it is possible to suppress lowering of impedance between pads as in the first and second embodiments. Accordingly, an effect is provided that deterioration of signal quality can be suppressed as compared with conventional techniques.

### Fourth Embodiment

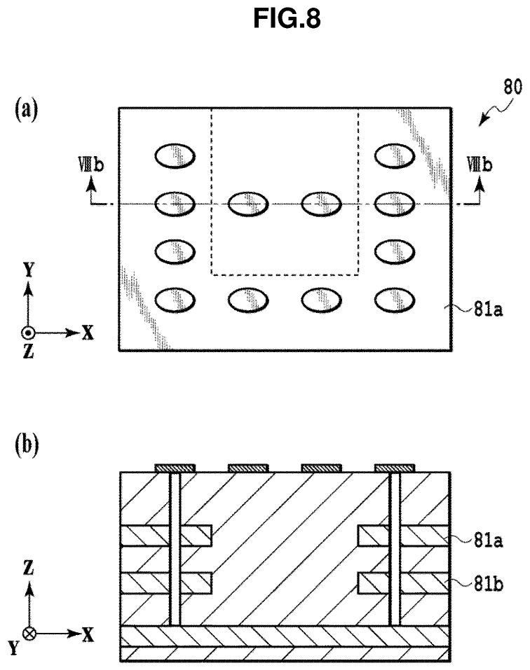

FIG. 8 is a diagram illustrating a structure of the PCB 80 according to the fourth embodiment of the present disclosure, FIG. 8(a) is a plan view of the PCB 80 as viewed from an upper surface side, and FIG. 8(b) is a cross-sectional view at a position of the section line VIIIb-VIIIb. As shown in FIG. 8, the PCB 80 according to the fourth embodiment of the present disclosure includes a differential signal pair including a first signal pad and a second signal pad adjacent to the first signal pad on an upper surface of a substrate so as to be connected with a BGA radio frequency module (e.g., the BGA radio frequency module 10, 40, 60, or 70) described above via solder balls, a first ground pad disposed adjacent to the first signal pad, a second ground pad disposed adjacent to the second signal pad, at least one third ground pad disposed at a position spaced from the first signal pad more than a first distance between the first signal pad and the first ground pad and a second distance between the second signal pad and the second ground pad, and at least one fourth ground pad disposed at a position spaced from the second signal pad more than the first distance and the second distance.

Furthermore, in the PCB 80 according to the fourth embodiment of the present disclosure, the ground pads are connected with a ground plane in a lower layer of the stacked substrate by through-hole vias, while the signal pads are configured to be electrically connected with surface layer wiring installed on the surface layer of the PCB and connected with external terminals. Moreover, in some of the ground planes 81a and 81b, a part immediately below the signal pad is eliminated in a rectangular shape. Note that, although the ground planes 81a and 81b each have a rectangular shape in FIG. 8, the shape may be arbitrary as long as a part immediately below the signal pad is eliminated.

In an optical communication module in which a BGA radio frequency module (e.g., the BGA radio frequency module 10, 40, or 60) is installed on the PCB 80, the distance between each of the signal pads and the ground plane is longer than that of the PCB 20 of the conventional technique. As a result, capacitive coupling between the ground plane and the signal pads is reduced, and therefore, lowering of impedance can be prevented and lowering of signal quality can be suppressed.

Note that the BGA radio frequency module installed on the PCB 80 has a similar effect in any form of the BGA radio frequency module described herein, including the conventional technique, as long as the signal pads and the ground pads are arranged to face each other.

Moreover, as in the first embodiment, the arrangement in the BGA radio frequency module 60 is not limited to a quadrangular shape as long as the above-described distance is obtained. Moreover, each pad may further include a ceramic coat restraint (not shown) for strength reinforcement. In addition, as in the second embodiment, the coupling may be made by sharing at least some of the signal pads and at least some of the ground pads.

### INDUSTRIAL APPLICABILITY

As described above, the BGA radio frequency module, the PCB, and the optical communication module in which at least one of the BGA radio frequency module or the PCB is installed according to the present disclosure can suppress impedance lowering as compared with conventional techniques. Accordingly, application to a small-sized optical transceiver is expected.

1. A BGA radio frequency module comprising:
a module member;
a differential signal pair, wherein the differential signal pair is disposed on a back surface of the module member and includes a first signal pad and a second signal pad adjacent to the first signal pad;
a first ground pad disposed adjacent to the first signal pad;
a second ground pad disposed adjacent to the second signal pad;
at least one third ground pad disposed at a position spaced from the first signal pad more than a first distance between the first signal pad and the first ground pad and a second distance between the second signal pad and the second ground pad; and
at least one fourth ground pad disposed at a position spaced from the second signal pad more than the first distance and the second distance.

2. The BGA radio frequency module according to claim 1, having a structure, wherein the structure includes a plurality of the differential signal pairs is included, and at least one of the ground pads is shared.

3. The BGA radio frequency module according to claim 1, wherein at least one of the first signal pad, the second signal pad, the first ground pad, the second ground pad, the third ground pad, or the fourth ground pad further comprises a ceramic coat for strength reinforcement.

4. The BGA radio frequency module according to claim 1, wherein at least one of the first signal pad or the second signal pad has a shape wherein the shape is scraped off at least a part in a direction of an adjacent signal pad or an adjacent ground pad.

5. A substrate for a BGA radio frequency module, comprising:
a differential signal pair, wherein the differential signal pair is disposed on a back surface of a substrate surface layer and includes a first signal pad and a second signal pad adjacent to the first signal pad;
a first ground pad disposed adjacent to the first signal pad;
a second ground pad disposed adjacent to the second signal pad;
at least one third ground pad disposed at a position spaced from the first signal pad more than a first distance between the first signal pad and the first ground pad and a second distance between the second signal pad and the second ground pad; and
at least one fourth ground pad disposed at a position spaced from the second signal pad more than the first distance and the second distance.

6. The substrate for a BGA radio frequency module according to claim 5, further comprising:
a stacked substrate wherein a plurality of dielectric portions and a plurality of ground planes are stacked; and
a through-hole via that electrically connects the ground pads and the ground planes,
wherein at least a part of the ground planes has a structure wherein the structure is eliminated a part immediately below the signal pads.

7. An optical communication module comprising the BGA radio frequency module according to claim 1.

8. An optical communication module comprising the substrate for a BGA radio frequency module according to claim 5.
